(19) United States
(12) Patent Application Publication
(10) Pub. No.: US 2015/0279904 A1
(43) Pub. Date: Oct. 1, 2015

(54) MAGNETIC TUNNEL JUNCTION FOR MRAM DEVICE

(71) Applicant: Spin Transfer Technologies, Inc., Fremont, CA (US)

(72) Inventors: Mustafa Pinarbasi, Morgan Hill, CA (US); Bartek Kardasz, Pleasanton, CA (US)

(73) Assignee: Spin Transfer Technologies, Inc., Fremont, CA (US)

(21) Appl. No.: 14/242,419

(22) Filed: Apr. 1, 2014

(51) Int. Cl. H01L 27/22; H01L 43/12; H01L 43/10; H01L 43/02; H01L 43/08

(52) U.S. Cl. CPC H01L 27/222; H01L 43/02; H01L 43/08; H01L 43/10; H01L 43/12

(57) ABSTRACT

A magnetoresistive random-access memory device with a magnetic tunnel junction stack having a significantly improved performance of the free layer in the magnetic tunnel junction structure. The memory device includes an antiferromagnetic structure and a magnetic tunnel junction structure disposed on the antiferromagnetic structure. The magnetic tunnel junction structure includes a reference layer and a free layer with a barrier layer sandwiched therebetween. Furthermore, a capping layer including a tantalum nitride film is disposed on the free layer of the magnetic tunnel junction structure.

### BACKGROUND

1. Field

The present patent document relates generally to spin-transfer torque magnetic random access memory and, more particularly, to a magnetic tunnel junction stack having significantly improved performance of the free layer in the magnetic tunnel junction structure.

2. Description of the Related Art

Magnetoresistive random-access memory (“MRAM”) is a non-volatile memory technology that stores data through magnetic storage elements. These elements are two ferromagnetic plates or electrodes that can hold a magnetic field and are separated by a non-magnetic material, such as a non-magnetic metal or insulator. In general, one of the plates has its magnetization pinned (i.e., a “reference layer”), meaning that this layer has a higher coercivity than the other layer and requires a larger magnetic field or spin-polarized current to change the orientation of its magnetization. The second plate is typically referred to as the free layer and its magnetization direction can be changed by a smaller magnetic field or spin-polarized current relative to the reference layer.

MRAM devices store information by changing the orientation of the magnetization of the free layer. In particular, based on whether the free layer is in a parallel or anti-parallel alignment relative to the reference layer, either a “1” or a “0” can be stored in each MRAM cell. Due to the spin-polarized electron tunneling effect, the electrical resistance of the cell change due to the orientation of the magnetic fields of the two layers. The cell's resistance will be different for the parallel and anti-parallel states and thus the cell's resistance can be used to distinguish between a “1” and a “0”. One important feature of MRAM devices is that they are non-volatile memory devices, since they maintain the information even when the power is off. The two plates can be sub-micron in lateral size and the magnetization direction can still be stable with respect to thermal fluctuations.

A newer technique, spin transfer torque or spin transfer switching, uses spin-aligned (“polarized”) electrons to change the magnetization orientation of the free layer in the magnetic tunnel junction. In general, electrons possess a spin, a quantized number of angular momentum intrinsic to the electron. An electrical current is generally unpolarized, i.e., it consists of 50% spin up and 50% spin down electrons. Passing a current though a magnetic layer polarizes electrons with the spin orientation corresponding to the magnetization direction of the magnetic layer (i.e., polarizer), thus produces a spin-polarized current. If a spin-polarized current is passed to the magnetic region of a free layer in the magnetic tunnel junction device, the electrons will transfer a portion of their spin-angular momentum to the magnetization layer to produce a torque on the magnetization of the free layer. Thus, torque can switch the magnetization of the free layer, which, in effect, writes either a “1” or a “0” based on whether the free layer is in the parallel or anti-parallel states relative to the reference layer.

FIG. 1 illustrates a magnetic tunnel junction (“MTJ”) stack 100 for a conventional MRAM device. As shown, stack 100 includes one or more seed layers 110 provided at the bottom of stack 100 to initiate a desired crystalline growth in the above-deposited layers. A pinning layer 112 is disposed on top of seed layers 110 and a synthetic antiferromagnetic layer (“SAF layer”) 120 is disposed on top of the pinning layer 112. Furthermore, MTJ 130 is deposited on top of SAF layer 120. MTJ 130 includes the reference layer 132, a barrier layer (i.e., the insulator) 134, and the free layer 136. It should be understood that reference layer 132 is actually part of SAF layer 120, but forms one of the ferromagnetic plates of MTJ 130 when the barrier layer 134 and free layer 136 are formed on reference layer 132. The first magnetic layer in the synthetic antiferromagnetic structure 120 is exchange coupled to the pinning layer 112, which causes, through antiferromagnetic coupling, the magnetization of the reference layer 132 to be fixed. Furthermore, a nonmagnetic spacer 140 is disposed on top of MTJ 130 and a perpendicular polarizer 150 is disposed on top of the nonmagnetic spacer 140. Perpendicular polarizer 150 is provided to polarize a current of electrons (“spin-aligned electrons”) applied to MTJ structure 100. Further, one or more capping layers 160 can be provided on top of perpendicular polarizer 150 to protect the layers below on MTJ stack 100. Finally, a hard mask 170 is deposited over capping layers 160 and is provided to pattern the underlying layers of the MTJ structure 100, using a reactive ion etch (RIE) process.

MRAM products having MTJ structures, such as stack 100 illustrated in FIG. 1, are already being used in large data storage devices. However, these MTJ structures require large switching currents that limit their commercial applicability. There are at least two critical parameters that control the required size of the switching current: effective magnetization M_{eff} (i.e., in-plane magnetization) and the damping constant for the free layer structure. Some existing designs have attempted to lower the required switching current by reducing the thickness of the free layer structure. While such a design facilitates perpendicular component of the magnetization that effectively lowers the M_{eff}, the measurable reduction of M_{eff} only occurs when the free layer is very thin (e.g., 1 nanometer). However, such a thin free layer has severe consequences including: (1) a significant reduction of tunneling magnetoresistance value (“TMR”); (2) a lower thermal stability; and (3) an increased damping constant for the free layer. Accordingly, there is a strong felt need for a magnetic tunnel junction layer stack with a significantly improved performance of the free layer in the MTJ structure.

### SUMMARY

An MRAM device is disclosed that has a magnetic tunnel junction stack having a significantly improved performance of the free layer in the magnetic tunnel junction structure that requires significantly lower switching currents for MRAM applications.

In one embodiment, the MRAM device includes an antiferromagnetic structure and a magnetic tunnel junction structure disposed on the antiferromagnetic structure. The magnetic tunnel junction structure includes a reference layer and a free layer with a barrier layer sandwiched therebetween. Furthermore, a capping layer including a tantalum nitride film that is disposed on the free layer of the magnetic tunnel junction structure.

In another embodiment, the tantalum nitride capping layer of the magnetic device has a thickness between 0.1 and 10 nanometers.

In another embodiment, the tantalum nitride capping layer of the magnetic device has a thickness of approximately 1.0 nanometer.

In another embodiment, the tantalum nitride capping layer of the magnetic device has a thickness of approximately 10 nanometers.

In another embodiment, the tantalum nitride capping layer of the magnetic device is disposed directly on the free layer.

In another embodiment, the magnetic device further includes a nonmagnetic spacer disposed on the tantalum nitride capping layer and a perpendicular polarizer disposed on the nonmagnetic spacer, such that the perpendicular polarizer polarizes a current of electrons applied to the magnetic device.

In another embodiment, the magnetic device is an orthogonal spin torque structure.

In another embodiment, the magnetic device is a collinear magnetized spin-transfer torque structure.

In another embodiment, the tantalum nitride capping layer of the magnetic device is formed on the free layer by a thin film sputter process with a tantalum target and a nitrogen gas.

In another embodiment, the reference layer, the free layer, the barrier layer and the tantalum nitride capping layer of the magnetic device collectively form a magnetic tunnel junction.

In another embodiment, the reference layer and the free layer of the magnetic device each comprise a CoFeB thin film layer having a thickness of approximately 2.3 nm.

In another embodiment, the barrier layer of the magnetic device is MgO and has a thickness of approximately 1.02 nm.

In another embodiment, the exemplary magnetic device forms a bit cell of a memory array.

### BRIEF DESCRIPTION OF THE DRAWINGS

The accompanying drawings, which are included as part of the present specification, illustrate the presently preferred embodiments and, together with the general description given above and the detailed description given below, serve to explain and teach the principles of the MTJ devices described herein.

FIG. 1 illustrates a conventional MTJ stack for an MRAM device.

FIG. 2 illustrates an MTJ layer stack in accordance with an exemplary embodiment of the new MTJ layer stack described herein.

The figures are not necessarily drawn to scale and the elements of similar structures or functions are generally represented by like reference numerals for illustrative purposes throughout the figures. The figures are only intended to facilitate the description of the various embodiments described herein; the figures do not describe every aspect of the teachings disclosed herein and do not limit the scope of the claims.

### DETAILED DESCRIPTION

A magnetic tunnel junction (“MTJ”) layer stack is disclosed herein. Each of the features and teachings disclosed herein can be utilized separately or in conjunction with other features and teachings. Representative examples utilizing many of these additional features and teachings, both separately and in combination, are described in further detail with reference to the attached drawings. This detailed description is merely intended to teach a person of skill in the art further details for practicing preferred aspects of the present teachings and is not intended to limit the scope of the claims. Therefore, combinations of features disclosed in the following detailed description may not be necessary to practice the teachings in the broadest sense, and are instead taught merely to describe particularly representative examples of the present teachings.

In the following description, for purposes of explanation only, specific nomenclature is set forth to provide a thorough understanding of the MTJ structure described herein. However, it will be apparent to one skilled in the art that these specific details are not only exemplary.

The various features of the representative examples and the dependent claims may be combined in ways that are not specifically and explicitly enumerated in order to provide additional useful embodiments of the present teachings. It is also expressly noted that all value ranges or indications of groups of entities disclose every possible intermediate value or intermediate entity for the purpose of original disclosure, as well as for the purpose of restricting the claimed subject matter. It is also expressly noted that the dimensions and the shapes of the components shown in the figures are designed to help to understand how the present teachings are practiced, but not intended to limit the dimensions and the shapes shown in the examples.

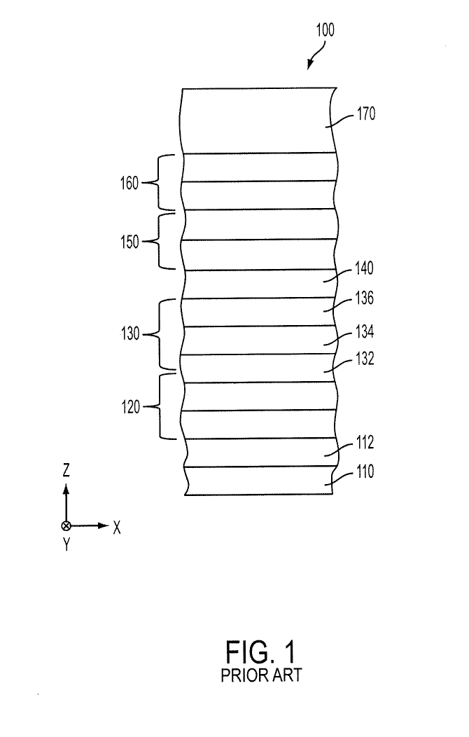

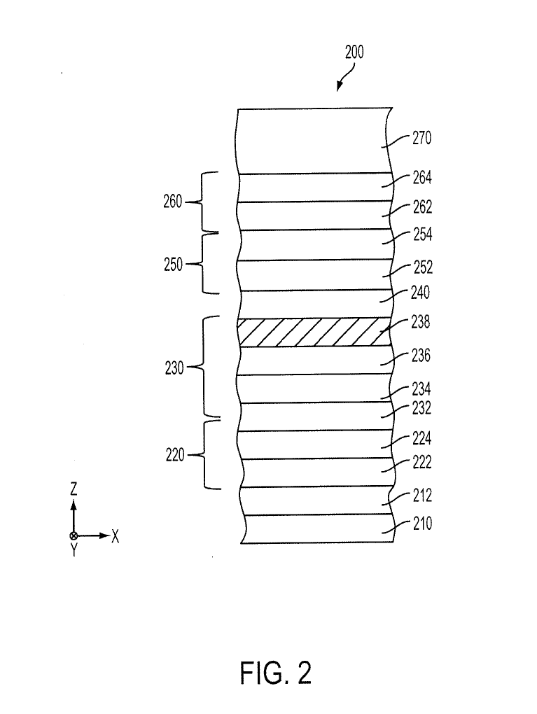

Referring to FIG. 2, an MTJ layer stack 200 is shown in accordance with an exemplary embodiment. MTJ stack 200 is an improved design of MTJ stack 100 illustrated in FIG. 1. For illustrative purposes, each of the layers in the MTJ stack 200 are formed in an x,y plane and each have a thickness in the z-axis direction.

MTJ stack 200 includes one or more seed layers 210 provided at the bottom of stack 200 to initiate a desired crystalline growth in the above-deposited layers (discussed below). In the exemplary embodiment, the seed layers 210 can be 3 Ta/40 CuN/5 Ta laminate (as used herein a “slash,” /, indicates a laminated structure starting with the layers at the bottom of the structure beginning from the left of the “slash,” /.), such that the seed layers include a 3 nm layer of tantalum, a 40 nm layer of copper nitride, and a 5 nm layer of tantalum.

Above the seed layers 210 is a pinning layer 212 and a synthetic antiferromagnetic (“SAF”) structure 220. According to an exemplary embodiment, pinning layer 212 is platinum manganese PtMn alloy preferably with a thickness of approximately 22 nm. In the exemplary embodiment, the SAF structure 220 is composed of three layers, layer 222, layer 224 and the reference layer 232 (discussed below). Preferably, layer 222 is a cobalt iron alloy preferably with a thickness of approximately 2.1 nm, and layer 224 is a ruthenium metal preferably with a thickness of approximately 0.90 nm.

An MTJ structure 230 is formed on top of the SAF structure 220. The MTJ structure 230 includes three separate layers, namely, reference layer 232 formed in the SAF structure 220, barrier layer 234, and free layer 236. In the exemplary embodiment, reference layer 232 and free layer 236 are cobalt-iron-boron (Co—Fe—B) alloy thin films. In the exemplary embodiment, each CoFeB thin film layer has a thickness of approximately 2.3 nm. The exchange coupling between reference layer 232 and pinning layer 12 strongly pins the magnetization of the reference layer 232 in a constant direction as discussed above. Furthermore, in the exemplary embodiment, barrier layer 234 is formed from an oxide of magnesium MgO. As shown, the MgO barrier layer 234 is disposed between the reference layer 232 and free layer 236 and serves as the insulator between the two layers as discussed above. The MgO barrier layer 234 preferably has a thickness of approximately 1.02 nm. Preferably, the thickness of MgO barrier layer 234 is thin enough that a current through it can be established by quantum mechanical tunneling of the spin polarized electrons.

Conventionally, for MTJ structures, the interaction between the barrier layer and the free layer is generally fixed, but the layers than can be deposited on top of the free layer can widely vary and can be enhanced to improve the characteristics of free layer. A feature of the MTJ stack 200 is the deposition of a very thin layer of tantalum nitride TaN capping material 238 on top of the free layer 236. In the exemplary embodiment, the thickness of the TaN capping material is between 0.1 and 10 nm, preferably approximately 1 nm or 2 nm. It should be appreciated to one skilled in the art that the desired thickness of 1 nm or 2 nm may vary slightly due to manufacturing variations. As will be discussed in detail below, the addition of the TaN capping material 238 on free layer 236 provides highly compressive stress (i.e., increased capacity of stack 200 to withstand compressive loads) and also significantly improves the parameters of free layer 236 over conventional designs. TaN capping material 238 cannot have a thickness over approximately 10 nm as it would completely or substantially eliminate the orthogonal polarizer effect and significantly decrease the functionality and accuracy of the memory device.

In the exemplary embodiment, an orthogonal spin torque structure that employs a spin-polarizing layer magnetized perpendicularly to free layer 236 to achieve large initial spin-transfer torques is described. As shown, MTJ stack 200 includes a nonmagnetic spacer 240 disposed on the TaN capping material 238 and perpendicular polarizer 250 disposed on the nonmagnetic spacer 240. Perpendicular polarizer 250 is provided to polarize a current of electrons (“spin-aligned electrons”) applied to MTJ stack 200, which in turn can change the magnetization orientation of free layer in 236 of the MTJ stack 200 by the torque exerted on free layer 236 from polarized electrons carrying angular momentum perpendicular to the magnetization direction of the free layer 236. Furthermore, the nonmagnetic spacer 240 is provided to insulate perpendicular polarizer 250 from MTJ structure 230. In the exemplary embodiment, the nonmagnetic spacer 240 is comprised of a copper laminate having a thickness of approximately 10 nm. In the exemplary embodiment, perpendicular polarizer 250 is comprised of two laminate layer 252, 254. Preferably, the first layer 252 is a laminate layer of 0.3 Co/[0.6 Ni/0.09 Co]×3 and the second layer 254 is a laminate layer composed of 0.21 Co/[0.9 Pd/0.3 Co]×6. Although the exemplary embodiment is provided for an orthogonal spin torque structure, it should be appreciated to one skilled in the art that the inventive design of providing a TaN capping material 238 on the free layer 236 can also be implemented for a collinear magnetized spin-transfer torque MRAM device.

As further shown in FIG. 2, one or more capping layers 260 are provided on top of perpendicular polarizer 250 to protect the layers below of MTJ stack 200. In the exemplary embodiment, capping layers 260 can be composed of a first laminate layer 262, preferably of 2 nm Pd layer, and a second laminate layer 264, preferably of 5 nm Cu and 7 nm Ru.

A hard mask 270 is deposited over capping layers 260 and may comprise a metal such as tantalum Ta, for example, although alternatively hard mask 270 may comprise other materials. Preferably, the Ta hard mask 270 has a thickness of approximately 70 nm. Hard mask 270 is opened or patterned and is provided to pattern the underlying layers of the MTJ stack 200, using a reactive ion etch (RIE) process, for example.

As noted above, a feature of the MTJ stack 200 of the exemplary embodiment is the deposition of a very thin layer of tantalum nitride TaN capping material 238 on top of the free layer 236. Conventionally, different sets of materials, such as body centered cubic materials like Ta, Cr and the like, have been applied as capping layers to free layers of MTJ structures. However, none of these designs have provided significant improvement in the performance parameters of the free layer of the MTJ structure while also decreasing the required switching current for optimal operation.

Tests have been conducted comparing the performance parameters of the MTJ described herein with conventional design configurations of the prior art. Tables 1 and 2 illustrate the compared performance parameters. In particular, Table 1 illustrates a comparison of the performance parameters between a 10 nm Cu free layer cap for a conventional orthogonal MTJ structure and the inventive structure of a TaN capping material 238 on free layer 236 in accordance with the exemplary embodiment of the MTJ described herein. Table 1 illustrates data for TaN cap 238 having thicknesses of 1.0 nm, 2.0 nm and 10 nm.

TABLE 1

| | | 10 nm | 10 nm | 2.0 nm | 10 nm |
|---|---|---|---|---|---|
| Performance | | Cu | TaN | TaN | TaN |
| Parameter | Units | Cap | Cap | Cap | Cap |
| M_{s, Free layer} *t | [emu/cm²] | 345 | 269 | 260 | 248 |
| Hc_{, Free layer} | [mT] | 1.25 | 0.75 | 0.75 | 087 |
| 4πM_{eff} [T] | [T] | 1.01 | 0.76 | 0.77 | 0.78 |
| Free layer | | | | | |
| H_{shift, Free layer} | [mT] | 3.0 | 5.0 | 5.0 | 4.2 |
| Damping | | 0.017 | 0.011 | 0.0072 | 0.007 |
| Constant (α) | | | | | |
| H_{C}, Polarizer | [T] | 0.26 | 0.33 | 0.36 | 0.35 |
| TMR | % | 84 | 124 | 131 | 130 |
| RA | [Ohm μm²] | 4.3 | 4.5 | 5.6 | 5.0 |

As noted above, the effective magnetization M_{eff} (i.e., in-plane magnetization) and the damping constant are two of the critical performance parameters for the free layer structure of an MTJ device. As illustrated in Table 1, by depositing a TaN capping layer on top of the free layer of the MTJ device, the effective magnetization M_{eff} is decreased by over 20% for each thickness of the TaN capping layer as compared with the conventional Cu capping layer. Moreover, the damping constant for a free layer having a 1.0 nm TaN capping layer is 35% less than the damping constant of free layer having a 10 nm Cu capping layer, and the damping constant for a free layer having a 2.0 nm or 10 nm TaN capping layer only is 58% less than the damping constant of free layer having a 10 nm Cu capping layer only. Notably, Table 1 further illustrates that the TMR % also significantly improves for the inventive MTJ structure having a free layer with a TaN capping layer as compared with a conventional MTJ structure having a free layer with a Cu capping layer.

Table 2 illustrates a comparison of the performance parameters between a 1.0 Ta free layer cap and the inventive structure of a TaN capping material 238 on free layer 236 in accordance with the exemplary embodiment of the MTJ described herein. Table 2 also illustrates data for TaN capping material 238 having thicknesses of 1.0 nm, 2.0 nm and 10 nm.

TABLE 2

| | | 1.0 nm | 1.0 nm | 2.0 nm | 10 nm |
|---|---|---|---|---|---|
| Performance | | Ta | TaN | TaN | TaN |
| Parameter | Units | Cap | Cap | Cap | Cap |
| M_{s, Free layer} *t | [emu/cm²] | 277 | 269 | 260 | 248 |
| Hc_{, Free layer} | [mT] | 1.5 | 0.75 | 0.75 | 087 |
| 4πM_{eff} [T] | [T] | 1.07 | 0.76 | 0.77 | 0.78 |
| Free layer | | | | | |
| H_{shift, Free layer} | [mT] | 3.9 | 5.0 | 5.0 | 4.2 |
| Damping | | 0.015 | 0.011 | 0.0072 | 0.007 |
| Constant (α) | | | | | |
| H_{C}, Polarizer | [T] | 0.39 | 0.33 | 0.36 | 0.35 |
| TMR | % | 144 | 124 | 131 | 130 |
| RA | [Ohm μm²] | 5.3 | 4.5 | 5.6 | 5.0 |

As illustrated in Table 2, by depositing a TaN capping layer on top of the free layer of the MTJ device, the effective magnetization M_{eff} is decreased by over 27% for each thickness of the TaN capping layer as compared with the conventional MTJ device with a free layer having a 1.0 nm Ta capping layer. Moreover, the damping constant for a free layer having a 1.0 nm TaN capping layer is 26% less than the damping constant of free layer having a 1.0 nm Ta capping layer, and the damping constant for a free layer having a 2.0 nm or 10 nm TaN capping layer is over 50% less than the damping constant of free layer having a 1.0 nm Ta capping layer. Accordingly, the comparison of free layer with TaN cap compared with the prior art designs, as illustrated in Tables 1 and 2, demonstrate that the performance parameters are significantly improved in view of the new inventive design.

All of the layers of MTJ stack 200 illustrated in FIG. 2 can be formed by a thin film sputter deposition system as would be appreciated by one skilled in the art. The thin film sputter deposition system can include the necessary physical vapor deposition (PVD) chambers, each having one or more targets, an oxidation chamber and a sputter etching chamber. Typically, the sputter deposition process involves a sputter gas (e.g., oxygen, argon, or the like) with an ultra-high vacuum and the targets can be made of the metal or metal alloys to be deposited on the substrate. In the preferred embodiment, the deposition of the TaN capping material 238 involves providing a tantalum target and a nitrogen sputter gas to provide the thin TaN film on the free layer 236 using the sputter deposition system. It should be appreciated that the remaining steps necessary to manufacture MTJ stack 200 are well-known to those skilled in the art and will not be described in detail herein so as not to unnecessarily obscure aspects of the disclosure herein.

It should be appreciated to one skilled in the art that a plurality of MTJ stacks 200 can be manufactured and provided as respective bit cells of an STT-MRAM device. In other words, each MTJ stack 200 can be implemented as a bit cell for a memory array having a plurality of bit cells.

The above description and drawings are only to be considered illustrative of specific embodiments, which achieve the features and advantages described herein. Modifications and substitutions to specific process conditions can be made. Accordingly, the embodiments in this patent document are not considered as being limited by the foregoing description and drawings.

What is claimed is:

1. A magnetic device, comprising:
an antiferromagnetic structure including a reference layer;
a barrier layer disposed on the reference layer;
a free layer disposed on the barrier layer;
a thin tantalum nitride capping layer disposed on the free layer, wherein the thin tantalum nitride capping layer comprises a thickness between 0.1 and 10 nanometers, and which keeps the damping constant of the free layer to 0.011 or lower;
a nonmagnetic spacer disposed on the thin tantalum nitride capping layer, the nonmagnetic spacer comprised of a copper laminate;
a perpendicular polarizer layer disposed on the nonmagnetic spacer, the perpendicular polarizer layer magnetized perpendicularly to free layer, thereby forming an orthogonal spin transfer torque structure; and
wherein the reference layer, the free layer, the barrier layer and the thin tantalum nitride capping layer collectively form a magnetic tunnel junction.

2. (canceled)

3. The magnetic device according to claim 1, wherein the thin tantalum nitride capping layer comprises a thickness of approximately 1.0 nanometer.

4. The magnetic device according to claim 1, wherein the thin tantalum nitride capping layer comprises a thickness of approximately 10 nanometers.

5. The magnetic device according to claim 1, wherein the thin tantalum nitride capping layer is disposed directly on the free layer.

6. The magnetic device according to claim 1
wherein the perpendicular polarizer disposed on the nonmagnetic spacer, such that the perpendicular polarizer polarizes a current of electrons applied to the magnetic device.

7. The magnetic device according to claim 6, wherein the magnetic device is an orthogonal spin transfer torque structure.

8. (canceled)

9. The magnetic device according to claim 1, wherein the thin tantalum nitride capping layer is formed on the free layer by a thin film sputter process with a tantalum target and a nitrogen gas.

10. (canceled)

11. The magnetic device according to claim 1, wherein the reference layer and the free layer each comprise a CoFeB thin film layer having a thickness of approximately 2.3 nm.

12. The magnetic device according to claim 11, wherein the barrier layer comprise MgO and has a thickness of approximately 1.02 nm.

13. A memory array comprising:
at least one bit cell including:
an antiferromagnetic structure including a reference layer;
a barrier layer disposed on the reference layer;
a free layer disposed on the barrier layer;
a thin tantalum nitride capping layer disposed on the free layer, wherein the thin tantalum nitride capping layer comprises a thickness between 0.1 and 10 nanometers, and which keeps the damping constant of the free layer to 0.011 or lower;
a nonmagnetic spacer disposed on the thin tantalum nitride capping layer, the nonmagnetic spacer comprised of a copper laminate;
a perpendicular polarizer layer disposed on the nonmagnetic spacer, the perpendicular polarizer layer magnetized perpendicularly to free layer, thereby forming an orthogonal spin transfer torque structure; and
wherein the reference layer, the free layer, the barrier layer and the thin tantalum nitride capping layer collectively form a magnetic tunnel junction.

14. (canceled)

15. The memory array according to claim 13, wherein the thin tantalum nitride capping layer of the at least one bit cell comprises a thickness of approximately 1.0 nanometer.

16. The memory array according to claim 13, wherein the thin tantalum nitride capping layer of the at least one bit cell comprises a thickness of approximately 10 nanometers.

17. The memory array according to claim 13, wherein the thin tantalum nitride capping layer of the at least one bit cell is disposed directly on the free layer.

18. The memory array according to claim 13, wherein
the perpendicular polarizer polarizes a current of electrons applied to the magnetic device.

19. The memory array according to claim 18, wherein the at least one bit cell is an orthogonal spin transfer torque structure.

20. (canceled)

21. The magnetic device according to claim 1, wherein the nonmagnetic spacer is approximately 10 nm thick.

22. The memory array according to claim 13, wherein the nonmagnetic spacer is approximately 10 nm thick.
